(19) United States
(12) Patent Application Publication
(10) Pub. No.: US 2012/0279549 A1
(43) Pub. Date: Nov. 8, 2012

(54) ORGANIC PHOTOVOLTAIC CELL AND MODULE COMPRISING SUCH A CELL

(75) Inventors: Mathieu Urien, Vincennes (FR); Fabien Lienhart, Paris (FR)

(73) Assignee: SAINT-GOBAIN GLASS FRANCE, Courbevoie (FR)

(21) Appl. No.: 13/520,055

(22) PCT Filed: Dec. 22, 2010
(86) PCT No.: PCT/FR2010/052877

§ 371 Date: Jun. 29, 2012

(30) Foreign Application Priority Data
Dec. 30, 2009 (FR) 0959668

(51) Int. Cl. H01L 51/44; H01L 27/30; H01L 51/48

(52) U.S. Cl. 136/244; 438/98; 136/256; 257/E51.012

(57) ABSTRACT

An organic photovoltaic cell comprising a substrate, a first electrode formed on the substrate, an organic photoactive medium comprising an electron donor and an electron acceptor, and a second electrode comprising a conductive mesh, the first electrode being located between the substrate and the second electrode. The cell comprises an insulating mesh formed on the first electrode. The conductive mesh is formed on the insulating mesh. The insulating mesh and the conductive mesh define together apertures for receiving the photoactive medium, said apertures being able to receive the photoactive medium after the first electrode, the insulating mesh and the conductive mesh have been deposited on the substrate.

The present invention relates to the field of organic photovoltaic cells.

Photovoltaic cells are electronic components that, when exposed to light, generate electricity.

In general three generations of photovoltaic cells may be distinguished.

“First-generation” cells consist of two electrodes between which is interposed a bulk semiconductor wafer (generally made of silicon) having a thickness of the order of one hundred microns and p-doped and n-doped regions in order to create a p-n junction. The semiconductor forms what is called the photoactive medium, inside of which the light is absorbed, thus creating electron-hole pairs. The movement of these electrons and holes toward their respective electrodes generates an electrical potential across the electrodes and thus a source of electrical current.

The ratio between the solar energy received and the electrical energy generated, called the cell efficiency, is about 25% for the best cells.

However, the processes used to produce silicon wafers are very energy-intensive. Furthermore, silicon is rare. Therefore, finding less energy-intensive fabrication processes that used less silicon was of great advantage.

“Second-generation” cells have the main advantage of using less material. They make use of “thin films”. Thin films of material (of the order of a micron in thickness) are deposited on a substrate, for example a glass substrate. Thin films are used to form the electrodes and the semiconductor layers. The semiconductor is for example amorphous silicon (a-Si), copper indium diselenide (CIS), or cadmium telluride (CdTe).

Producing second-generation cells costs less. Their efficiency, which may reach 19% in the case of CIS cells, is lower than that of first-generation cells but the ratio between their efficiency and their fabrication cost is better.

“Third-generation” photovoltaic cells aim to further improve this ratio.

Among third-generation cells, what are called organic photovoltaic cells are in particular distinguished. These cells make use of a photoactive medium based on an organic (polymer or “small molecule”) semiconductor.

These cells in particular have two advantages. The photoactive medium may be deposited by solution coating using an inexpensive process and the substrate chosen may be flexible, thereby allowing the use of particularly economical production techniques such as roll-to-roll processing.

The present invention relates more particularly to an organic photovoltaic cell comprising:
a substrate;
a first electrode formed on the substrate;
an organic photoactive medium comprising an electron donor and an electron acceptor; and
a second electrode comprising a conductive mesh, the first electrode being located between the substrate and the second electrode.
   WO-A-2007/002376 describes, with reference to FIG. 2, a photovoltaic cell comprising a substrate on which is deposited an anode formed by a continuous film, a film of an electron-blocking material deposited on the anode, itself covered in succession by a photoactive medium, a film of a hole-blocking material, a mesh cathode, an adhesive film and a substrate.

To fabricate such a cell, the first electrode and the blocking film are deposited on the substrate for example at a first manufacturing site. The substrate equipped with the first electrode is then for example sent to another manufacturing site in order for the photoactive medium to be deposited by solution coating followed by deposition of the second electrode after the photoactive medium has been deposited. The second electrode cannot be even partially deposited on the substrate before the photoactive medium has been deposited.

The photoactive medium has the advantage of being inexpensive, in particular due to the simplicity of solution coating deposition and the small amount of material used, but the cost of the cell remains relatively high, in particular due to the processes used to produce the two electrodes.

One object of the invention is to provide an organic photovoltaic cell having a relatively low fabrication cost, in order to have a good ratio between its energy efficiency and its fabrication cost.

For this purpose, one subject of the present invention is a photovoltaic cell of the aforementioned type, characterized in that the cell comprises an insulating mesh formed on the first electrode, and in that the conductive mesh is formed on the insulating mesh, the insulating mesh and the conductive mesh defining together apertures for receiving the photoactive medium, said apertures being able to receive the photoactive medium after the first electrode, the insulating mesh and the conductive mesh have been deposited on the substrate.

The insulating mesh is formed on the first electrode so as to electrically isolate the second electrode from the first.

Such a cell, due to the insulating mesh and this particular arrangement of the insulating mesh and the conductive mesh, allows the first electrode and at least a part of the second electrode to be deposited on a given substrate before the photoactive medium has been deposited. As a result, the value added of the substrate before the photoactive medium has been deposited is higher. Furthermore, the fabrication process is easy to implement and the cost of producing the electrodes can be optimized, for example by forming the first electrode and the conductive mesh in the same deposition chamber.

The photovoltaic cell according to the invention furthermore allows the photoactive medium to be deposited by solution coating using an inexpensive process and the substrate chosen may be flexible, thereby allowing the use of particularly economical production techniques such as roll-to-roll processing.

The fabrication cost of such a cell is therefore relatively low.

According to particular embodiments of the invention, the cell comprises one or more of the following features, applied individually or in any technically possible combination:
the receiving apertures are closed off by the first electrode or by a film interposed between the first electrode and the insulating mesh;
the conductive mesh is formed by at least one electronically conductive film;
the conductive mesh has features allowing it to be obtained by deposition through a mask;
the insulating mesh and the conductive mesh have features allowing them to be obtained by deposition through the same mask;
the insulating mesh and the conductive mesh define a pattern of apertures that is irregular and random;
the receiving apertures defined by the conductive mesh extend the receiving apertures defined by the insulating mesh;
the receiving apertures are noncontiguous and spaced apart;
the apertures in the insulating mesh and in the conductive mesh have an average diameter between 5 and 100 μm, preferably between 6 and 20 μm;
the strands bounding the apertures in the insulating mesh and the conductive mesh have an average width between 500 nm and 10 μm, preferably between 600 nm and 2 μm;
the strands of the insulating mesh have an average height and the film or films of the insulating mesh have a resistivity or resistivities suitable for obtaining a resistance, for a thickness of the strands of the insulating mesh, sufficient to prevent a short-circuit between the first electrode and the second electrode;
the average diameter of the apertures, the average width of the strands, the average height of the strands and the resistivity or resistivities of the conductive film or films of the conductive mesh are for example chosen so that the conductive mesh has a sheet resistance between 1 and 20 Ω/□, preferably between 5 and 15 Ω/□, and more preferably between 8 and 10 Ω/□;
in which the second electrode comprises at least one conductive organic film, made of an electrically conductive organic material, the conductive organic film covering the photoactive medium;
the conductive organic film at least partially fills the apertures in the conductive mesh;
the conductive organic film at least partially fills the apertures in the insulating mesh;
the photoactive medium at least partially fills the apertures in the insulating mesh;
the photoactive medium does not even partially fill the apertures in the conductive mesh;
the cell comprises, between the photoactive medium and the conductive mesh, a hole-blocking film if the second electrode is the cathode or an electron-blocking film if the second electrode is the anode;
the second electrode comprises at least one conductive film, made of an electrical conductor, the conductive mesh comprising said at least one conductive film;
the first electrode comprises at least one conductive film, made of an electrical conductor;
the conductive film or films of the conductive mesh have for example a resistivity or resistivities lower than or equal to 10⁻³ Ω·cm, for example lower than or equal to 10⁻⁵ Ω·cm;
the thickness of the conductive mesh is for example between 100 nm and 2000 nm;
the insulating mesh comprises at least one insulating film made of a dielectric;
the insulating film or films of the insulating mesh has/have a resistivity higher than or equal to 10⁵ Ω·cm, for example higher than or equal to 10⁷ Ω·cm; and
said at least one conductive film of the first electrode is continuous.

Another subject of the invention is a photovoltaic module comprising a plurality of photovoltaic cells connected in series, characterized in that the photovoltaic cells are as described above, the second electrode of a photovoltaic cell k making electrical contact with the first electrode of an immediately adjacent photovoltaic cell k+1, and the second electrode of the photovoltaic cell k+1 making electrical contact with the first electrode of an immediately adjacent photovoltaic cell k+2, where k is a number between 1 and N-2, N being the number of photovoltaic cells in the module.

Another subject of the invention is a process for fabricating a photovoltaic cell comprising in succession steps of:
depositing on a substrate at least one first conductive film, made of an electrically conductive material, so as to form a first electrode;
forming a mask on said at least one first film;
depositing at least one insulating film, made of a dielectric, through said mask so as to form an insulating mesh;
depositing at least one second conductive film, made of a conductive material, through said mask so as to form a conductive mesh of a second electrode;
removing the mask; and
depositing a photoactive medium by solution coating so as to fill at least partially apertures that are defined together by the insulating mesh and the conductive mesh.

According to particular embodiments of the invention, the process comprises one or more of the following features, applied individually or in any technically possible combination:
the step of forming the mask comprises:
   a step of depositing a film based on a solution of stabilized colloidal particles dispersed in a solvent; and
   a step of drying said film until a network of interstices is obtained forming a mask for deposition of a mesh,
the colloidal particle solution is deposited by dip coating; and
the process comprises a step of depositing, on the photoactive medium, and on the conductive mesh at least one conductive organic film, made of a conductive material, so as to form the second electrode with said at least one second conductive film.

Another subject of the invention is a process for fabricating a photovoltaic module comprising in succession steps of:
depositing on a substrate at least one first conductive film, made of an electrically conductive material, so as to form a first electrode;
forming a mask on said at least one first conductive film;
depositing at least one insulating film, made of a dielectric, through said mask so as to form an insulating mesh;
depositing at least one second conductive film, made of a conductive material, through said mask so as to form a conductive mesh of a second electrode;
removing said mask; and
depositing a photoactive medium by solution coating so as to fill at least partially apertures that are defined together by the insulating mesh and the conductive mesh.

According to particular embodiments of the invention, the process comprises one or more of the following features, applied individually or in any technically possible combination:
the process furthermore comprises a step of depositing at least one conductive organic film, made of a conductive material, on the photoactive medium and optionally on the conductive mesh, so as to form the second electrode with the conductive mesh; and
the process furthermore comprises
   after said at least one second conductive film has been deposited and before the photoactive medium has been deposited, a first step of laser-ablating previously deposited films along a plurality of first parallel lines along the length of the substrate in order to divide the module into a plurality of photovoltaic cells, the laser being configured to remove, along the first lines, said at least one first conductive film, said at least one insulating film and said at least one second conductive film, the photoactive medium filling the slits formed by the first laser ablation along the first lines;
   after the photoactive medium has been deposited and before said at least one conductive organic film has been deposited, a second laser-ablating step along second parallel lines adjacent the first lines, the laser being configured to remove, along the second lines, the photoactive medium, said at least one insulating film and said at least one second conductive film, but without removing said at least one first conductive film, said at least one conductive organic film filling the slits formed by the second laser ablation along the second lines; and
   after said at least one conductive organic film has been deposited, a third laser-ablating step along third parallel lines adjacent the second lines on the side opposite the first lines, the laser being configured to remove along the third lines said at least one conductive organic film, the photoactive medium, said at least one second conductive film and said at least one insulating film, but without removing said at least one first conductive film.

The invention will be better understood on reading the following description, given merely by way of example and with reference to the appended drawings, in which:

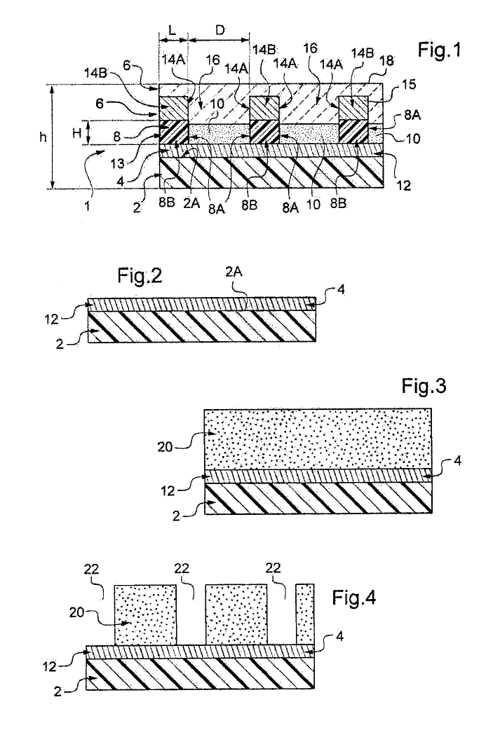

FIG. 1 is a partial schematic view, in cross section, of a photovoltaic cell according to the invention;

FIGS. 2 to 4 and 5 to 9 are views, analogous to FIG. 1, illustrating various steps in the cell fabrication process;

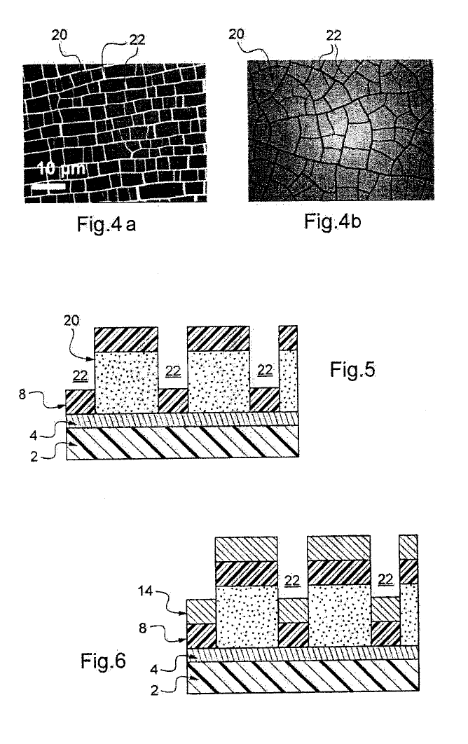

FIGS. 4a and 4b are top views of exemplary masks; and

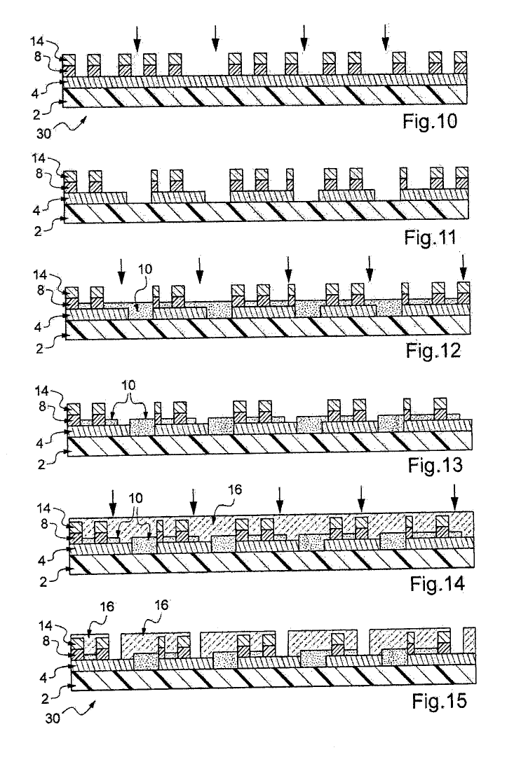

FIGS. 10 to 15 are partial schematic views, in cross section, illustrating the fabrication of a photovoltaic module comprising a plurality of photovoltaic cells, as shown in FIG. 1, connected together in series.

The photovoltaic cell 1 according to the invention is an organic photovoltaic cell.

The expression “organic photovoltaic cell” is generally understood to mean a photovoltaic cell that has an organic photoactive medium i.e. a photoactive medium composed mainly of an organic semiconductor. The invention is however of course not limited to the organic and inorganic semiconductors listed below.

Organic semiconductors are characterized by regular alternation between single and double bonds, which allows electron delocalization along the backbone: they are referred to as conjugated systems. It is possible to class organic semiconductors into two categories: low molar mass molecules, commonly called “small molecules”; and polymers. The expression “organic semiconductor” is understood to mean all-organic semiconductors but also hybrid organic/inorganic semiconductors, in particular organometallic semiconductors, with the exception of conventional inorganic semiconductors based on germanium, silicon, etc.

The organic photovoltaic cell 1 according to the invention comprises, as illustrated in FIG. 1, a substrate 2, a first electrode 4, a second electrode 6, an insulating mesh 8 separating the first electrode 4 and the second electrode 6, and an organic photoactive medium 10 arranged to make electrical contact with the first electrode 4 and the second electrode 6.

The drawings are not to scale, in order to make them clearer, because the thickness differences between the substrate 2 and the other films 4, 6, 8, 10 are substantial, for example about 500 times different. Furthermore, the drawings are schematic and the meshes of the cells and modules of course comprise many more strands.

The substrate 2 acts as a support for the deposition of the material films forming various elements of the cell 1. The substrate 2 has a topside 2A on which the various deposited films form films parallel to the plane of the topside 2A.

The first electrode 4 is formed by a continuous film 12 of an electrically conductive material, which is deposited either directly on the substrate 2 or with one or more films interposed, for example Si₃N₄ or SnZnO.

The expression “a film A formed (or deposited) on a film B” is understood, throughout this text, to mean a film A formed either directly on the film B, and therefore in contact with the film B, or formed on the film B with one or more films interposed between the film A and the film B.

The film 12 is continuous over its extent.

The insulating mesh 8 is obtained by depositing, on the first electrode 4, an insulating film 13, made of a dielectric and in the form of a mesh. The deposition is carried out through a mask, as described in more detail below. The first electrode 4 is thus located between the substrate 2 and the insulating mesh 8.

It should be noted that the term “mesh” is understood to mean an array of a given material formed by strands that bound between them through-apertures and that join one another. Each strand is connected to any other strand of the mesh either directly, when the two strands join each other, or via other strands of the mesh.

The second electrode 6 comprises a conductive mesh 14 and a conductive organic film 16 deposited by solution coating, which is optional.

The conductive mesh 14 is obtained by depositing, on the insulating mesh 8, through the same mask used to form the insulating mesh 8, a film 15, made of an electrically conductive material, or a multilayer stack.

The insulating mesh 8 and the conductive mesh 14 are juxtaposed and deposited on the first electrode 4. The insulating mesh 8 is sandwiched between the first electrode 4 and the conductive mesh 14.

After the conductive mesh 14 has been deposited and before the conductive organic film 16 has been deposited the photoactive medium 10 is deposited.

The photoactive medium 10 is arranged in the apertures 8A in the insulating mesh 8 by depositing it through the apertures 14A in the conductive mesh 14. The apertures 8A thus define, with the apertures 14A, photoactive-medium-receiving apertures for receiving the photoactive medium 10 after the first electrode 4, the insulating mesh 8 and the conductive mesh 14 have been deposited.

The conductive organic film 16 is deposited on the photoactive medium 10 and on the conductive mesh 14. The conductive organic film 16 thus covers the photoactive medium 10 and supplies an electrically conductive medium between the photoactive medium 10 and the conductive mesh 14.

Because they are deposited through the same mask, the meshes 8 and 14 have identical cross sections, i.e. they are identical in a cross section through a surface parallel to the plane of the topside 2A of the substrate 2, and the meshes 8 and 14 are aligned such that their respective apertures 8A, 14A respectively face each other and extend each other.

The meshes 8 and 14 each have many apertures, respectively 8A and 14A, that define the receiving apertures.

The receiving apertures 8A, 14A are noncontiguous and spaced apart. They are closed off by the first electrode 4, i.e. the first electrode bounds the bottom of the apertures. However, as a variant, the receiving apertures 8A, 14A are closed off by a continuous film interposed between the insulating mesh 8 and the first electrode 4.

The conductive organic film 16 closes off the receiving apertures 8A, 14A on the side opposite the first electrode 4. As a variant an intermediate film may also be interposed. It should be noted that before the photoactive medium and the conductive organic film 16 have been deposited, the receiving apertures 8A, 14A are blind apertures. They are then closed off by the deposition of the conductive organic film 16 or an intermediate film.

The strands, respectively 8B, 14B, of the meshes 8, 14, extend along the thickness “h” of the cell 1. The meshes 8 and 14 thus form together a continuous mesh pattern along the thickness “h”.

The patterns formed by the strands 8B, 14B of the meshes 8 and 14 are irregular and random because the mask is formed by drying and cracking a colloidal suspension, as explained in more detail below.

The apertures 8A, 14A have for example a mean diameter “D” between 5 and 100 μm, preferably between 6 and 20 μm. The strands 8B and 14B have for example an average width “L” between 500 nm and 10 μm, preferably between 600 nm and 2 μm. (It should be noted that, throughout this text, ranges are inclusive of their limits).

The ratio between the average diameter D of the apertures and the average width L of the strands is for example between 5 and 20, preferably between 10 and 20.

The insulating mesh 8 for example has a thickness between 50 nm and 2 μm.

The conductive mesh 14 for example has a thickness between 100 nm and 2 μm.

The size of the average diameter D of the apertures 8A, 14A and the average width L and height H of the strands 8B, 14B result from a compromise between several parameters: the energy transmission of the electrode 6, the resistance of the second electrode 6, the resistance for a thickness of the strands 8B of the insulating mesh 8, and the fabrication cost.

Maximizing the ratio between the average diameter D of the apertures and the average width L of the strands maximizes the energy transmission through the second electrode 6.

However, the resistance of the second electrode 6 increases as the width L of the strands decreases. This resistance may then be reduced by increasing the average height H of the strands, i.e. the thickness of the conductive mesh 14, so as to increase the strand cross-sectional area and thereby reduce the resistance.

However, the increase in the average height H of the strands may lead to (depending on the production technique used) an increase in the production cost of the conductive mesh 14, as the time taken to deposit it may increase.

This example of electrode parameter optimization illustrates the necessary compromise between the various geometric parameters of the meshes.

The strands 8B of the insulating mesh 8 have an average height H and the film or films of the insulating mesh 8 have a resistivity or resistivities suitable for obtaining a resistance, for a thickness of the strands 8B of the insulating mesh 8, sufficient to prevent a short-circuit between the first electrode 4 and the second electrode 6.

The insulating film or films of the insulating mesh 8 for example have a resistivity higher than or equal to 10⁵ Ω·cm, for example higher than or equal to 10⁷ Ω·cm.

The average diameter D of the apertures 14A, the average width L of the strands 14B, the average height H of the strands 14B and the resistivity or resistivities of the conductive film or films 15 of the conductive mesh 14 are, for example, chosen so that the conductive mesh 14 has a sheet resistance between 1 and 20 Ω/□, preferably between 5 and 15 Ω/□, and more preferably between 8 and 10 Ω/□. (It should be noted that the sheet resistance is by definition measured parallel to the substrate 2).

The conductive film or films 15 of the conductive mesh 14 for example have a resistivity or resistivities lower than or equal to 10⁻³ Ω·cm, for example lower than or equal to 10⁻⁵ Ω·cm.

In the example illustrated, the photoactive medium 10 is arranged in the apertures 8A of the insulating mesh 8 and partially fills the apertures 8A of the mesh 8.

As explained above, the conductive organic film 16 ensures electrical contact between the photoactive medium 10 and the conductive mesh 14.

However, as a variant, the photoactive medium completely fills the apertures 8A in the insulating mesh 8 and fills, at least partially, the apertures 14A in the conductive mesh 14. The conductive organic film is then optional because the photoactive medium makes contact with the conductive mesh 14.

Generally, the photovoltaic cell 1 is configured such that the photoactive medium 10 makes electrical contact with the first electrode 4 and with the second electrode 6.

It should be noted that the expression “in electrical contact” does not necessarily imply “contact”, hole- and/or electron-blocking films for example being interposed between the photoactive medium 10 and the electrodes 4, 6.

The photoactive medium 10 is here formed by a single photoactive film comprising a mixture of an electron donor and an electron acceptor. However, as a variant it could be for example two films, one being an electron donor and the other being an electron acceptor.

The conductive organic film 16 of the second electrode 6 fills, at least partially, the remaining volume of the apertures 8A, 14A of the insulating mesh 8 and of the conductive mesh 14.

As explained above, the conductive film 16 is thus arranged to electrically connect the photoactive medium 10 and the conductive mesh 14. This feature has the effect of improving charge extraction, which in particular has the advantage of allowing the second electrode 6 to be more transparent relative to a variant without a conductive organic film 16.

The conductive organic film 16 for example is thick enough to completely fill the apertures in the conductive mesh 14 and cover the conductive mesh 14. It then bounds a topside 18 that is continuous over the extent of the cell 1.

The preferred materials used to make the cell 1 according to the invention, and certain characteristics of the films, will now be described in more detail.

Light is intended to penetrate the cell 1 illustrated from the side opposite the substrate 2. The first electrode 4 has thus been chosen to be “reflecting”, whereas the second electrode 6 has been chosen to be “transparent”. For certain applications, the first electrode 4 and the second electrode 6 could however both be chosen to be transparent, for example in a glazing unit including photovoltaic cells, which glazing unit is desired to be semitransparent.

In the example illustrated, the first electrode 4 is a cathode, whereas the second electrode 6 is an anode.

The first electrode 4 is then made of a metal having a lower work function than the second electrode 6. This may for example be Al (aluminum), Ag (silver), Mg (magnesium) or else Ca (calcium).

The first electrode 4 illustrated is formed by a single film 12, but, as a variant, it comprises a multilayer stack (also called a multilayer) of more than one film (for example a multilayer of various metals chosen from the metals mentioned above).

The first electrode 4 for example has a sheet resistance between 0.01 and 1 Ω/□.

The film or films of the first electrode 4 are for example deposited by magnetron sputtering.

The insulating mesh 8 is preferably made of a dielectric that can be deposited by magnetron sputtering. This may for example be SiO₂ (silicon oxide) or Si₃N₄ (silicon nitride).

The insulating mesh 8 illustrated comprises a single film 13 but, as a variant, the insulating mesh 8 consists of a multilayer of more than one film.

The film or films 13 of the insulating mesh 8 is/are for example deposited by magnetron sputtering, for example by reactive magnetron sputtering.

The conductive mesh 14 for example consists of a single film, for example made of ITO (indium tin oxide), or even of a multilayer of more than one film, for example an Ag-based multilayer.

The thickness of the conductive mesh 14 is for example between 100 nm and 2000 nm.

The film or films of the conductive mesh 14 are for example deposited by magnetron sputtering, for example by reactive magnetron sputtering.

The conductive organic film 16 is for example a PEDOT (poly(3,4-ethylenedioxythiophene)) film or a colloidal solution of ITO nanoparticles. The conductive film 16 is for example deposited by slot coating. This may also be a transparent conductive film (or multilayer), deposited by magnetron sputtering, having a high work function—such as ITO or ZnO:Al—or an Ag-based multilayer having, as sublayer in direct contact with the photoactive medium 10, a film of a high-work-function material such as ITO or ZnO:Al.

As a variant, the cell 1 comprises a multilayer of more than one organic film 16.

The conductive organic film 16 (or the multilayer of conductive organic films) for example has a thickness between 10 and 2000 nm.

The organic photoactive medium 10 is for example a solution of a mixture of an electron donor and an electron acceptor. This may for example be a solution of P3HT (poly(3-hexylthiophene)) and PCBM ([6,6]-phenyl-C₆₁ butyric acid methyl ester)

The thickness of the organic photoactive medium 10 is for example between 1 nm and 2000 nm, for example between 1 and 300 nm.

The substrate 2 is for its part for example made of glass, plastic or metal. It is preferably flexible. It is for example made from PET (polyethylene terephthalate) or of PI (polyimide). It comprises, as a variant, a plurality of material films.

In applications in which it is desired for the photovoltaic cell 1 to be transparent, the substrate 2 is for example chosen to be transparent and associated with transparent electrodes 4, 6.

The organic photovoltaic cell according to the invention has a number of advantages.

As explained above, the photovoltaic cell 1 allows all or a part of the second electrode 6 to be deposited before the organic photoactive medium 10 has been deposited.

The first electrode 4, the insulating film 8 and at least a part of the second electrode 6 may thus be deposited within a given deposition chamber, thereby reducing the number of tools needed and reducing the fabrication cost.

It should be noted that the deposition of the second part of the second electrode 6, namely the conductive organic film 16 (which is optional), does not require a magnetron sputterer, this deposition being carried out by solution coating.

It should also be noted that the conductive organic film 16 alone, i.e. without the conductive mesh, is not sufficient, its conductivity not being high enough.

This also has the advantage of increasing the value added of the substrate 2 on which the photoactive medium 10 is later deposited.

The structure of the second electrode 6 also makes good transparency and good conductance possible because of the structure of the second electrode 6, which is at least in part a mesh, and the arrangement of the photoactive medium 10 in the apertures of the insulating mesh 8.

The measured sheet resistance is in fact less than 9 Ω/□ and the light transmission under illuminant D65 is greater than 85%.

The conductive organic film 16 increases the contact area between the second electrode 6 and the photoactive medium 10. It improves charge extraction.

The cell 1 comprises, in another variant, one or more films of an electron-blocking material between the anode 4 and the photoactive medium 10 (for example based on PEDOT:PSS or MoO₃) and/or one or more films of a hole-blocking material between the cathode 6 and the photoactive medium 10 (for example based on TiO₂ or ZnO). It should however be noted that interposing a blocking film between the second electrode 6 and the photoactive medium is anticipated only in the case where the photoactive medium 10 does not make contact with the conductive mesh 14.

When hole- and/or electron-blocking films are interposed, the photoactive medium 10 is then not in direct contact with the first electrode 4 and the second electrode 6. Generally, as explained above, it is simply necessary for the cell 1 to be configured to allow electrons to flow from the photoactive medium 10 toward and into the cathode and to allow holes to flow from the photoactive medium 10 toward and into the anode, i.e. for the photoactive medium to be in “electrical contact” with the first and second electrodes.

As a variant, the first electrode 4 is the anode whereas the second electrode 6 is the cathode. The anode is then for example chosen to be transparent, light being intended for example to penetrate the cell from the substrate side. According to this variant, the first electrode is preferably a film or a multilayer such that the last film has a high work function, such as ITO or ZnO:Al. The electrode may also consist of a multilayer based on Ag (or any other conductive metal) and terminated by said high-work-function film, in which the films between the Ag films and the high-work-function film are all conductive.

According to this variant, the second electrode may consist of a low-work-function metal such as Al or Mg. The photovoltaic cell is then semitransparent because the degree of coverage of the metal mesh serving as the cathode is sufficiently low that light may pass through.

As yet another variant, at least one of the meshes 8 and 14 is not obtained by deposition through a mask. For example a screen-print etching technique may be used consisting in depositing the materials corresponding to the insulating mesh 8 and to the conductive mesh 14 over the entire surface and then depositing, for example by screen printing, an etchant paste on the regions which will not be covered by the materials of the insulating mesh 8 and of the conductive mesh 14.

Also as a variant, the conductive film 12 of the first electrode is not continuous.

Another subject of the invention is a process for fabricating a photovoltaic cell.

As illustrated in FIGS. 2 to 9, the process comprises a first step of placing the substrate 2 in position and depositing on the substrate 2 the conductive film 12, made of an electrically conductive material, so as to form the first electrode 4 (FIG. 2). The film is either deposited directly on the topside 2A of the substrate 2 or films are interposed between the substrate 2 and the first electrode 4.

Next, a film based on a solution of stabilized colloidal particles dispersed in a solvent is deposited by solution coating, which film is designed to form a mask 20 that allows a mesh to be formed by deposition through the mask.

This may for example be spin coating, curtain coating, dip coating or spray coating, for example spin coating of a simple emulsion of stabilized acrylic-copolymer-based colloidal particles in water. These may for example be colloidal particles having a characteristic size between 80 and 100 nm, for example those sold by DSM under the Neocryl XK 52 brand name.

The reader may for example refer to WO-A-2008/132397, which describes examples of suitable masks.

Next, the film incorporating the colloidal particles is dried so as to evaporate the solvent (FIG. 4). This drying is carried out using any suitable process (for example hot-air drying).

During this drying step, the system self-arranges, forming patterns embodiments of which are shown in FIGS. 4a and 4b. A stable mask 20 having a structure characterized by the width of the strands and the space between the strands is obtained without an anneal. The pattern of the strands is irregular and random.

Next, the process comprises a step of depositing the insulating mesh 8 through the mask 20 (FIG. 5), i.e. in the interstices 22 defined by the cracks in the mask 20. These interstices 22 are for example filled to 50% of the thickness of the mask 20, or less.

This deposition phase may be carried out for example by magnetron sputtering, for example by reactive magnetron sputtering, or by evaporation.

The material part that is deposited on the mask 20 will be removed with the mask and therefore does not form part of the insulating mesh 8.

Next, the process comprises a step of depositing a second conductive film 15, made of a conductive material, through the mask 20, analogously to the insulating mesh 8, in order to form a first part of the second electrode 6 (FIG. 6).

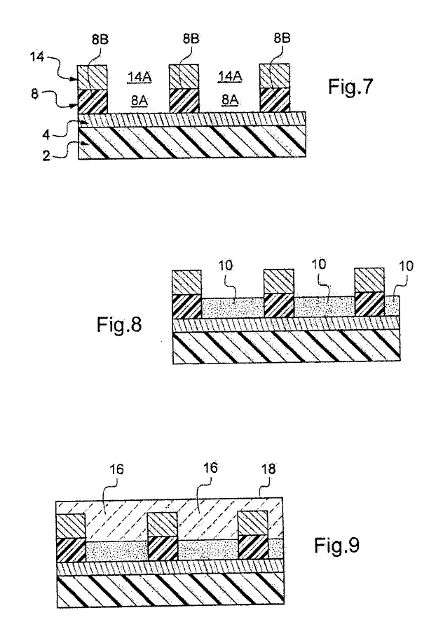

Next, in order to reveal the mesh structure of the insulating mesh 8 and of the conductive mesh 14, the mask 20 is lifted off (FIG. 7).

This operation is made easier by the fact that the cohesion of the colloids results from weak Van der Waals forces (no binder or bonding resulting from an anneal). The colloidal mask 20 is then immersed in a water- and acetone-containing solution (the cleaning solution is chosen depending on the nature of the colloidal particles) and then rinsed so as to clear all the parts coated with colloids. This process may be accelerated by using ultrasonic vibrations to degrade the colloidal-particle mask and allow the appearance of the complementary parts (the network of interstices 22 filled with the material) to which the meshes 8, 14 conform.

After the mask 20 has been removed, the photoactive medium 10 is deposited by solution coating so as to fill at least partially the apertures that are defined together by the insulating mesh 8 and the conductive mesh 14 (FIG. 8). This may for example be spin coating.

Next, the process comprises a step of depositing a conductive organic film 16, made of a conductive organic material, on the photoactive medium 10 and on the conductive mesh 14 so as to form the second part of the second electrode 6.

Next, the cell 1 is for example encapsulated by lamination with one or more heat-cured vinyl acetylate (EVA) films, as is known per se.

Another subject of the present invention is a photovoltaic module 30, comprising a plurality of photovoltaic cells 1, as described above, connected in series, and its fabrication process.

FIGS. 10 to 15 illustrate various steps in the process for fabricating the module 30 according to the invention.

First, the steps shown in FIGS. 2 to 7 are carried out on a single substrate 2 so as to form the first electrode 4, the insulating mesh 8 and the conductive mesh 14 (see FIG. 10).

The process thus comprises in succession steps of:
depositing on the substrate 2 a conductive film 12, made of an electrically conductive material, so as to form the first electrode 4;
forming the mask 20 on the first film 12;
depositing an insulating film 13, made of a dielectric, through the mask 20 so as to form the insulating mesh 8;
depositing a film 15, made of a conductive material, through the mask 20 so as to form the conductive mesh 14; and
removing the mask 20.

Next, the process comprises a first ablating step, for example using a laser, of the previously deposited films 12, 13, 15, along a plurality of first parallel lines along the length of the substrate 2 in order to divide the module 30 into a plurality of photovoltaic cells 1 (see FIGS. 11 and 12).

The laser is configured to remove, along the first lines, the various layers 12, 13, 15 of the first electrode 4, the insulating mesh 8 and the conductive mesh 14. This may for example be a 1064 nm Nd:YAG laser frequency-doubled to emit at 532 nm.

Next, a photoactive medium 10 is deposited by solution coating so as to fill at least partially the receiving apertures that are defined together by the apertures 8A in the insulating mesh 8 and the apertures 14A in the conductive mesh 14 (FIG. 12). The photoactive medium 10 fills the slits formed, in the first electrode 4, by the first laser ablation along the first lines.

Next, a second laser ablation is carried out along second parallel lines adjacent the first lines (FIGS. 12 and 13).

The laser is configured to remove, along the second lines, the various films of the photoactive medium 10, the insulating mesh 8 and the conductive mesh 14, but without removing the first conductive film 12. This may be for example a 532 nm Nd:YAG laser.

Next, the conductive organic film 16 is deposited on the photoactive medium 10 and conductive mesh 14, so as to form with the conductive mesh 14 the second electrode 6.

The conductive organic film 16 fills the slits formed by the second laser ablation along the second lines.

Next, the process comprises a third laser-ablating step along third parallel lines adjacent the second lines, on the side opposite the first lines.

The laser is configured analogously to the second laser ablation (for example a 532 nm Nd:YAG laser) so as to remove along the third lines the conductive organic film 16, the photoactive medium 10 and the various films 13, 15 of the conductive mesh 4 and the insulating mesh 8, but without removing the first conductive film 12.

The process according to the invention has the advantage of allowing the various photovoltaic cells 1 to be formed on the module 30 at a reduced cost, whilst connecting them in series.

Thus fabricated, the photovoltaic module 30 comprises a plurality of photovoltaic cells connected in series, in which the second electrode of a photovoltaic cell k makes electrical contact with the first electrode of an immediately adjacent photovoltaic cell k+1, and the second electrode of the photovoltaic cell k+1 makes electrical contact with the first electrode of an immediately adjacent photovoltaic cell k+2, where k is a number between 1 and N-2, N being the number of photovoltaic cells in the module.

The module according to the invention has the same advantages as those described above for the cell 1.

The module and the cell according to the invention are furthermore suited to production using roll-to-roll processing, i.e. they can be produced on a flexible substrate that can be wound into rolls. This is a major advantage in terms of the production rate and ease of logistics.

1. An organic photovoltaic cell, comprising:
a substrate;
a first electrode formed on the substrate;
an organic photoactive medium comprising an electron donor and an electron acceptor; and
a second electrode comprising a conductive mesh, the first electrode being located between the substrate and the second electrode,
wherein the cell comprises an insulating mesh formed on the first electrode, and
wherein the conductive mesh is formed on the insulating mesh, the insulating mesh and the conductive mesh defining together apertures in the conductive mesh and the insulating mesh, which receive the photoactive medium after the first electrode, the insulating mesh, and the conductive mesh are deposited on the substrate.

2. The photovoltaic cell of claim 1, wherein the apertures are closed off by the first electrode or by a film interposed between the first electrode and the insulating mesh.

3. The photovoltaic cell of claim 1, wherein the insulating mesh and the conductive mesh comprise features that allow them to be obtained by deposition through a mask, which is the same for each mesh.

4. The photovoltaic cell of claim 1, wherein the insulating mesh and the conductive mesh define a pattern of the apertures that is irregular and random.

5. The photovoltaic cell of claim 1, wherein the apertures in the insulating mesh and the apertures in the conductive mesh have an average diameter between 5 and 100 μm.

6. The photovoltaic cell of claim 1, further comprising strands bound to the apertures in the insulating mesh and to the apertures the conductive mesh, wherein the strands have an average width between 500 nm and 10 μm.

7. The photovoltaic cell of claim 1, wherein the second electrode further comprises a conductive organic film comprising an electrically conductive organic material,
wherein the conductive organic film covers the photoactive medium.

8. The photovoltaic cell of claim 7, wherein the conductive organic film fills at least partially the apertures in the conductive mesh.

9. The photovoltaic cell of claim 8, wherein the conductive organic film fills at least partially the apertures in the insulating mesh.

10. The photovoltaic cell of claim 1, wherein the photoactive medium fills at least partially the apertures in the insulating mesh.

11. The photovoltaic cell of claim 10, wherein the photoactive medium does not even partially fill the apertures in the conductive mesh.

12. The photovoltaic cell of claim 11, further comprising, between the photoactive medium and the conductive mesh:
a hole-blocking film if the second electrode is a cathode; or
an electron-blocking film if the second electrode is an anode.

13. A photovoltaic module comprising:
a plurality of the photovoltaic cells of claim 1 connected in series,
wherein the second electrode of a photovoltaic cell (k) makes electrical contact with the first electrode of an immediately adjacent photovoltaic cell (k+1), and the second electrode of the photovoltaic cell (k+1) makes electrical contact with the first electrode of an immediately adjacent photovoltaic cell (k+2), wherein k is a number between 1 and N-2, and N is the number of photovoltaic cells in the module.

14. A process for fabricating a photovoltaic cell, the process comprising, in succession:
(I) depositing a first conductive film comprising an electrically conductive material on a substrate, to form a first electrode;
(II) forming a mask on the first conductive film;
(III) depositing an insulating film comprising a dielectric through the mask, so as to form an insulating mesh;
(IV) depositing a second conductive film comprising a conductive material through the mask, so as to form a conductive mesh of a second electrode;
(V) removing the mask; and
(VI) depositing a photoactive medium, by solution coating, to fill at least partially apertures that are defined together by the insulating mesh and the conductive mesh.

15. The process of claim 14, wherein the forming (II) comprises:
(II-a) depositing a film comprising a solution of stabilized colloidal particles dispersed in a solvent; and
(II-b) drying the film until a network of interstices is obtained, thereby forming the mask.

16. The process of claim 15, wherein the colloidal particle solution is deposited by dip coating.

17. The fabrication process of claims 14, further comprising, after (VI):
(VII) depositing, on the photoactive medium, and on the conductive mesh a conductive organic film comprising a conductive material, to form the second electrode with the second conductive film.

18. A process for fabricating a photovoltaic module, comprising, in succession:
(I) depositing a first conductive film comprising an electrically conductive material on a substrate, to form a first electrode;
(II) forming a mask on the first conductive film;
(III) depositing an insulating film comprising a dielectric through the mask, to form an insulating mesh;
(IV) depositing a second conductive film comprising a conductive material through the mask, to form a conductive mesh of a second electrode;
(V) removing the mask; and
(VI) depositing a photoactive medium, by solution coating, to fill at least partially apertures that are defined together by the insulating mesh and the conductive mesh.

19. The process of claim 18, further comprising, after (VI):
(VII) depositing a conductive organic film comprising a conductive material on the photoactive medium and optionally on the conductive mesh, to form the second electrode with the conductive mesh.

20. The process of claim 19, further comprising:
after (IV) and before (VI), laser-ablating the first conductive film, the insulating film, and the second conductive film along a plurality of first parallel lines along a length of the substrate, to divide the module into a plurality of photovoltaic cells, wherein the laser is configured to remove, along the first lines, the first conductive film, the insulating film, and the second conductive film, and the photoactive medium fills slits formed by the laser ablation along the first lines;
after (VI) and before (VII), a second laser-ablating along second parallel lines, which are adjacent to the first lines, wherein the laser is configured to remove, along the second lines, the photoactive medium, the insulating film, and the second conductive film, without removing the first conductive film, wherein the conductive organic film fills slits formed by the second laser ablation along the second lines; and
after (VII), a third laser-ablating along third parallel lines, which are adjacent to the second lines an opposite side from the first lines, wherein the laser is configured to remove along the third lines the conductive organic film, the photoactive medium, the second conductive film, and the insulating film, without removing the first conductive film.
